(19) United States
(12) Patent Application Publication
(10) Pub. No.: US 2011/0051000 A1
(43) Pub. Date: Mar. 3, 2011

(54) SET INFORMATION RECORDING DEVICE AND SET INFORMATION RECORDING SYSTEM

(75) Inventor: Nobuhiro Hara, Osaka (JP)

(73) Assignee: SANYO ELECTRIC CO., LTD., Osaka (JP)

(21) Appl. No.: 12/873,755

(22) Filed: Sep. 1, 2010

(30) Foreign Application Priority Data
Sep. 1, 2009 (JP) 2009-201178
Sep. 1, 2009 (JP) 2009-201179

(51) Int. Cl. H04N 5/44; H03M 13/09; G06F 11/10

(52) U.S. Cl. 348/553; 714/807; 714/E11.032; 348/E05.096

(57) ABSTRACT

A set information recording device records set information that is recorded in a recording unit of electronic equipment and equipment information indicating characteristic of the electronic equipment together. When the set information and the equipment information are input from the set information recording device to the electronic equipment, a deciding unit of the electronic equipment compares the input equipment information with the recorded equipment information in the recording unit so as to decide whether or not the input set information is appropriate.

This application is based on Japanese Patent Applications No. 2009-201178 filed on Sep. 1, 2009 and Japanese Patent Applications No. 2009-201179 filed on Sep. 1, 2009.

### BACKGROUND OF THE INVENTION

1. Field of the Invention

The present invention relates to a set information recording device which records set information of electronic equipment and a set information recording system including the set information recording device.

2. Description of Related Art

Recent years, electronic equipment such as a reception/reproduction apparatus for receiving and reproducing television broadcasting, which records set information for use in processing image signals and sound signals, comes into widespread use. Further, some of such electronic equipment can not only record the set information but also rewrite the set information in accordance with a user's instruction or the like.

For instance, there is proposed electronic equipment equipped with a nonvolatile memory which records set information of both before and after rewriting, so that the set information before rewriting can be restored easily after rewriting. In addition, for example, there is proposed a set information recording device that is connected to electronic equipment for use and rewrites set information of the electronic equipment with set information stored in the set information recording device.

However, the former electronic equipment has a problem that troublesome operation is required for rewriting the set information for each of the equipment. In particular, when an administrator or a manufacturer of the electronic equipment rewrites the set information, it is necessary to repeat the same operation many times, which is tiresome.

In contrast, if the latter set information recording device is used, the set information of a plurality of electronic equipment can be rewritten with the stored set information sequentially. However, if a human error or the like causes mistake of the set information recording device to be connected to the electronic equipment for another, the set information of the electronic equipment may be rewritten with incorrect information as a problem.

This problem may be suppressed by affixing a seal to the set information recording device or remarking information about the set information, so that the set information recording device can be distinguished apparently. However, much information is necessary for distinguishing the recorded set information accurately, and it is difficult to express the information so as to be distinguished apparently. Even if it can be expressed so as to be distinguished apparently, the steps are complicated. Further, the user is required to decide whether or not the set information is correct “on the basis of appearance of the set information recording device, which is tiresome.

### SUMMARY OF THE INVENTION

A set information recording system according to the present invention includes:

at least one electronic equipment; and

at least one set information recording device which records set information of the electronic equipment, in which

the electronic equipment includes a connection unit which communicates with the set information recording device, a recording unit which records set information and equipment information indicating its characteristic, and a deciding unit which decides whether or not the set information input to the electronic equipment is correct,

the set information recording device records the equipment information together with the set information which are input together via the connection unit, and

when the set information and the equipment information are input from the set information recording device to the electronic equipment, the deciding unit decides whether or not the set information input to the electronic equipment is appropriate by comparing the input equipment information with the stored equipment information in the recording unit.

The set information recording device according to the present invention records the set information of the electronic equipment together with the equipment information indicating characteristic of the electronic equipment, and supplies the recorded set information and equipment information to the electronic equipment or another electronic equipment.

The electronic equipment of the present invention includes:

a connection unit which performs communication with outside;

a recording unit which records set information of itself and equipment information indicating its characteristic; and

a deciding unit which decides whether or not the set information input to the electronic equipment is appropriate, in which

when the set information and the equipment information are input from outside via the connection unit, the deciding unit decides whether or not the set information input to the electronic equipment is appropriate by comparing the input equipment information with the recorded equipment information in the recording unit.

A set information recording system of the present invention includes:

at least one electronic equipment; and

at least one set information recording device which record set information of the electronic equipment, in which

the electronic equipment includes a connection unit which communicates with the set information recording device, a recording unit which records the set information, an additional information generating unit which generates additional information on the basis of the set information input to the set information recording device, and a notifying unit which notifies the additional information,

the set information recording device records the additional information together with the set information which are input together via the connection unit, and

the notifying unit notifies the additional information when the set information and the additional information are input from the electronic equipment to the set information recording device, and when the set information and the additional information are input from the set information recording device to the electronic equipment.

A set information recording system according to the present invention records the set information of the electronic equipment together with the additional information generated on the basis of the set information, and supplies the recorded set information and additional information to the electronic equipment or another electronic equipment.

Electronic equipment of the present invention includes:

a connection unit which performs communication with outside;

a recording unit which records set information of itself;

an additional information generating unit which generates additional information on the basis of set information output externally; and

a notifying unit which notifies the additional information, in which

the notifying unit notifies the additional information when the set information and the additional information are output via the connection unit, and when the set information and the additional information are input via the connection unit.

### BRIEF DESCRIPTION OF THE DRAWINGS

FIG. 1 is a block diagram illustrating a configuration of a set information recording system according to an embodiment of the present invention.

FIG. 2 is a flowchart illustrating a recording operation of Example 1 of the set information recording system according to an embodiment of the present invention.

FIG. 3 is a flowchart illustrating a reading operation of Example 1 of the set information recording system according to an embodiment of the present invention.

FIG. 4 is a flowchart illustrating a recording operation of Example 2 of the set information recording system according to an embodiment of the present invention.

FIG. 5 is a flowchart illustrating a reading operation of Example 2 of the set information recording system according to an embodiment of the present invention.

FIG. 6 is a flowchart illustrating a recording operation of Example 3 of the set information recording system according to an embodiment of the present invention.

FIG. 7 is a flowchart illustrating a reading operation of Example 3 of the set information recording system according to an embodiment of the present invention.

### DETAILED DESCRIPTION OF THE PREFERRED EMBODIMENTS

Meanings and effects of the present invention will be further clarified from the following description of embodiment. However, the embodiment described below is merely one of embodiments of the present invention, and meanings of the present invention and terms of elements are not limited to those described in the following description.

<Configuration of Set Information Recording System>

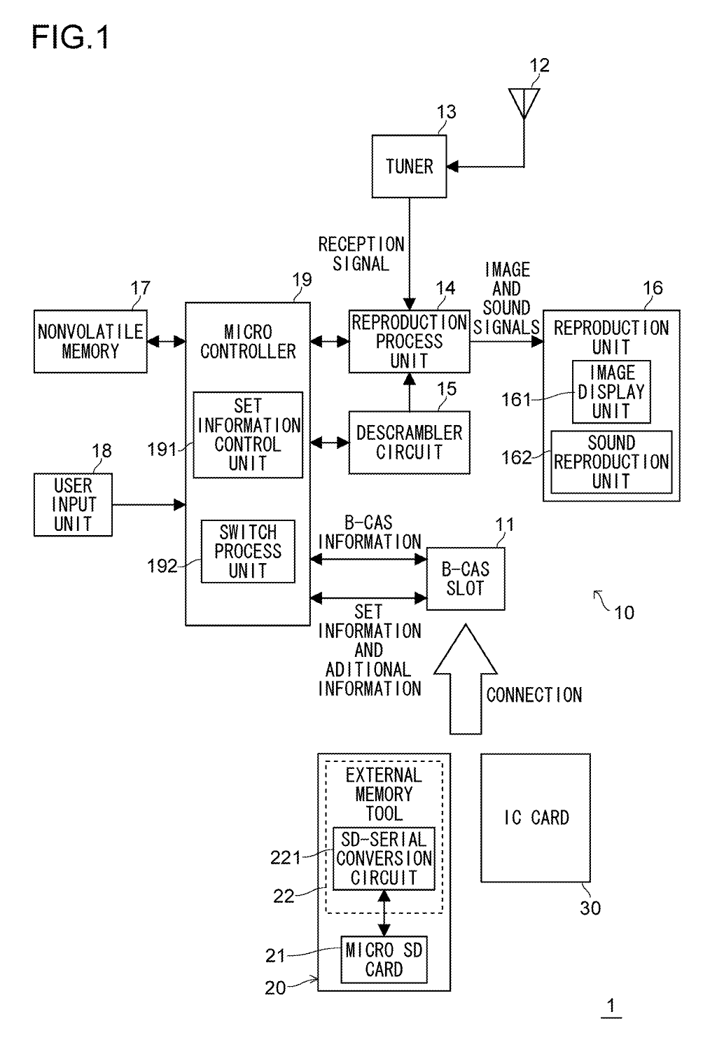

First, a configuration of the set information recording system according to an embodiment of the present invention will be described with reference to FIG. 1. FIG. 1 is a block diagram illustrating a configuration of the set information recording system according to an embodiment of the present invention.

As illustrated in FIG. 1, the set information recording system 1 according to an embodiment of the present invention includes an electronic equipment equipped with an interface with external equipment, and a set information recording device 20 that can be connected to the interface. Further, for specific description below, a reception/reproduction apparatus 10 which receives and reproduces digital broadcasting is described as an example of the electronic equipment, and a BS-Conditional Access Systems (B-CAS) slot 11 is described as an example of the interface.

The reception/reproduction apparatus 10 includes the B-CAS slot 11, an antenna 12 which receives broadcasting signals, a tuner 13 which obtains a desired frequency band signal from the broadcasting signal received by the antenna 12 and performs a predetermined process such as frequency conversion so as to generate and output a reception signal, a reproduction process circuit 14 which performs demodulation and decoding of the reception signal output from the tuner 13 and various processes using set information so as to generate and output image and sound signals, a descrambler circuit 15 which generates a descramble code for descrambling the reception signal and supplies the code to the reproduction process circuit 14, a reproduction unit 16 which reproduces the image and sound signals output from the reproduction process circuit 14, a nonvolatile memory 17 which records various information such as the set information, a user input unit 18 which inputs user's instruction, and a micro controller 19 which performs general control of the reception/reproduction apparatus 10.

The set information recording device 20 or an integrated circuit (IC) card 30 such as a B-CAS card is inserted into the B-CAS slot 11, and each of them is connected to the reception/reproduction apparatus 10. Then, set information and additional information (that will be described later in detail) recorded in the set information recording device 20 and B-CAS information recorded in the IC card 30 are read by the micro controller 19 via the B-CAS slot 11.

On the contrary, the set information and the additional information read from the nonvolatile memory 17 to the micro controller 19 are recorded in the set information recording device 20 via the B-CAS slot 11. In the same manner, when pay-broadcasting or the like is received, for example, the B-CAS information generated by the micro controller 19 is recorded in the IC card 30 via the B-CAS slot 11.

The micro controller 19 includes a set information control unit 191 which controls the set information, and a switch process unit 192 which switches circuit connection or the like appropriately in accordance with external equipment connected to the B-CAS slot 11 (or a type of information communicated via the B-CAS slot 11).

The reproduction unit 16 includes an image display unit 161 which processes and displays the image signal, and a sound reproduction unit 162 which processes and reproduces the sound signal. The image display unit 161 is constituted of a liquid crystal display panel, for example, while the sound reproduction unit 162 is constituted of a speaker, for example. Further, a size of a display screen of the image display unit 161 (for example, a diagonal length (inches) of a rectangular display screen) is referred to as a “panel size” in the following description.

The set information recording device 20 includes a micro secure digital (SD) card 21 in which the set information and the additional information are recorded, and an external memory tool 22 for connecting the B-CAS slot 11 with the micro SD card 21 so as to read the set information and the additional information from the micro SD card 21 or to write the set information and the additional information in the micro SD card 21. The micro SD card 21 is detachable (exchangeable) from the external memory tool 22.

In addition, the external memory tool 22 includes an SD-serial conversion circuit 221 which transmits the set information and the additional information read from the micro SD card 21 to the B-CAS slot 11 as serial signals and converts the set information and the additional information transmitted from the B-CAS slot 11 as serial signals into signals to be recorded in the micro SD card 21.

The set information recording device 20 has compatibility with at least the same model of reception/reproduction apparatus 10. Therefore, the set information recording device 20 can read the set information from one reception/reproduction apparatus 10 and record the set information in the same reception/reproduction apparatus 10 or another reception/reproduction apparatus 10. In other words, it is possible to backup the set information of one reception/reproduction apparatus 10 or to copy the set information of one reception/reproduction apparatus 10 to another reception/reproduction apparatus 10.

Note that it is possible to provide the compatibility not only between the same model of reception/reproduction apparatuses 10 but also between different models but the same type of reception/reproduction apparatuses 10 (for example, reception/reproduction apparatuses 10 having the same configuration as illustrated in FIG. 1 but having different panel size).

In addition, although the example described above uses the micro SD card 21 as a recording medium of the set information recording device 20, but other type of recording medium such as a universal serial bus (USB) memory may be used. In addition, as a communication method between the reception/reproduction apparatus 10 and the set information recording device 20 (for example, I²C or RS-232C, serial or parallel, wired or wireless), any method may be adopted. However, the interfaces of the B-CAS slot 11, the external memory tool 22, the SD-serial conversion circuit 221 and the like should support the recording medium and the communication method to be used.

In addition, the external memory tool 22 of set the information recording device 20 and the reception/reproduction apparatus 10 illustrated in FIG. 1 may be integrated and may have a configuration in which the recording medium such as the micro SD card 21 is detachable from the reception/reproduction apparatus 10 (in this case, the recording medium is the set information recording device). In addition, an interface only for the set information recording device 20 may be disposed in the reception/reproduction apparatus 10.

However, as illustrated in FIG. 1, it is preferred to use the B-CAS slot 11 as an existing configuration so that external memory tool 22 is detachable from the B-CAS slot 11. In this case, it is possible to avoid design change of the reception/reproduction apparatus 10, complication and cost increase of the configuration.

<Reception/Reproduction Operation>

Next, operations of the set information recording system 1 according to an embodiment of the present invention will be described with reference to the drawings. First, the reception/reproduction operation of the reception/reproduction apparatus 10 will be described with reference to FIG. 1.

When the reception/reproduction apparatus 10 performs the reception/reproduction operation, the IC card 30 is connected to the B-CAS slot 11. Then, the B-CAS information recorded in the IC card 30 (particularly, an IC code and a secret key of the card) is read by the micro controller 19 via the B-CAS slot 11 and is supplied to the descrambler circuit 15. In this case, the switch process unit 192 performs switching of the circuit connection or the like appropriately so that the obtained B-CAS information is input to the descrambler circuit 15.

The tuner 13 obtains a desired frequency band signal from the broadcasting signal received by the antenna 12. Further, frequency of the obtained signal is converted into a low frequency, and intensity of the signal is controlled to be an appropriate level so as to generate the reception signal. Further, the generated reception signal is input to the reproduction process circuit 14.

The reproduction process circuit 14 demodulates the reception signal by a demodulation method corresponding to a modulation method of the input reception signal (for example, quadrature phase shift keying (QPSK) or quadrature amplitude modulation (QAM)). The signal obtained by the demodulation includes a signal necessary for descrambling, and the micro controller 19 obtains the signal and supplied the same to the descrambler circuit 15. The descrambler circuit 15 uses the signal and the B-CAS information obtained from the IC card 30 so as to generate the descramble code necessary for descrambling the reception signal. The reproduction process circuit 14 performs various decoding such as decoding (descrambling) using the descramble code supplied from the descrambler circuit 15 and error correction.

In addition, the reproduction process circuit 14 performs an adjustment process on the decoded signal in order to generate a signal suitable for reproduction in the reproduction unit 16 (image and sound signals). In this case, the reproduction process circuit 14 is supplied with the set information read from the nonvolatile memory 17 by the set information control unit 191. The reproduction process circuit 14 performs an adjustment process on the decoded signal using the set information so as to generate the image and sound signals.

The image and sound signals generated by the reproduction process circuit 14 are reproduced by the reproduction unit 16. In particular, the image signal is displayed by the image display unit 161, and the sound signal is reproduced by the sound reproduction unit 162.

The set information may include information corresponding to display characteristic and reproduction characteristic of the image display unit 161 and the sound reproduction unit 162, for example, namely, information indicating correction contents for the signal so as to perform appropriate display and reproduction. In addition, for example, the set information may include information indicating various setting such as restrictions set by an administrator or a manufacturer (for example, suppression of a menu display, suppression of changing reception setting, maximum volume, and the like).

In addition, the user can change the set information by input of an instruction to the micro controller 19 via the user input unit 18. In this case, the set information control unit 191 records the instructed set information in the nonvolatile memory 17. Note that the nonvolatile memory 17 may have a configuration capable of recording a plurality of set information.

### Example 1

Next, a recording operation and a reading operation of Example 1 of the set information recording system 1 will be described with reference to the drawings. Note that the recording operation means an operation of recording the set information and the additional information supplied from the reception/reproduction apparatus 10 by the set information recording device 20. In addition, the reading operation means an operation of reading the set information and the additional information set information recorded by the recording device 20 by the reception/reproduction apparatus 10.

[Recording Operation]

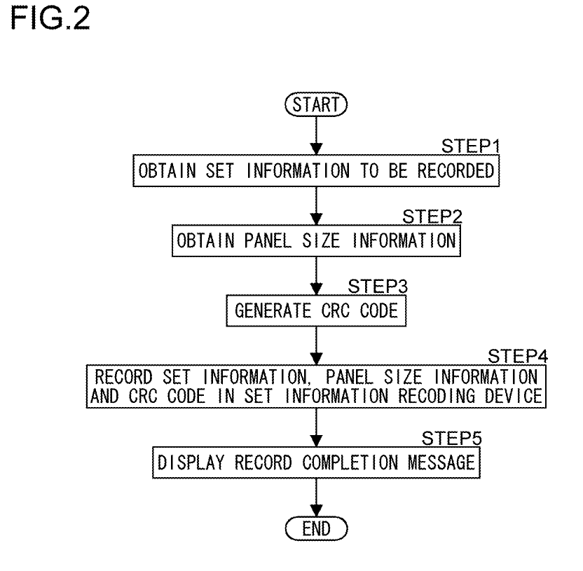

First, the recording operation of the set information recording system 1 of Example 1 will be described with reference to FIG. 2. FIG. 2 is a flowchart illustrating the recording operation of Example 1 of the set information recording system according to an embodiment of the present invention.

When the recording operation is performed, the set information recording device 20 is connected to the B-CAS slot 11 of the reception/reproduction apparatus 10. Further, for example, when the user instructs the micro controller 19 via the user input unit 18 to perform the recording operation, the reception/reproduction apparatus 10 switches to a state where the set information and the additional information are recorded in the set information recording device 20. In this case, the switch process unit 192 performs switching of the circuit connection or the like appropriately so that the set information and the additional information are recorded in the set information recording device 20 via the B-CAS slot 11.

The additional information includes equipment information indicating equipment characteristic of the reception/reproduction apparatus 10. Note that a case where panel size information is used as the equipment information is exemplified for specific description below. The panel size information is information indicating, for example, the above-mentioned panel size in inches as it is, and is recorded also in the conventional reception/reproduction apparatus for use in various applications.

Further, the additional information includes generated information that is generated on the basis of the set information and the panel size information. Note that a case where a cyclic redundancy check (CRC) code is used as the generated information is exemplified for specific description below. The CRC code means, for example, a remainder obtained when a bit string to be calculated (combination information of the set information and the panel size information) is divided by a predetermined generating polynomial (for example, 11000000000000101 (x¹⁶+x¹⁵+x²+x⁰) for CRC-16).

When the set information recording system 1 becomes the above-mentioned state so that the recording operation is started, the set information control unit 191 first reads and obtains the set information to be recorded from the nonvolatile memory 17 (STEP 1). Similarly, the set information control unit 191 obtains the panel size information from the nonvolatile memory 17 (STEP 2). Then, the set information control unit 191 generates the CRC code on the basis of the obtained set information and panel size information (STEP 3).

Then, the set information control unit 191 records the set information, the panel size information and the CRC code in the micro SD card 21 via the B-CAS slot 11 and the external memory tool 22 (STEP 4).

When the set information control unit 191 confirms that the set information, the panel size information and the CRC code are recorded in the micro SD card 21, it instructs the reproduction process circuit 14 to display a message indicating that the recording is completed. Then, the reproduction process circuit 14 generates the image signal in accordance with the instruction, so that the image signal is supplied to the image display unit 161 of the reproduction unit 16. Thus, the message indicating that the recording of the set information is completed is displayed on the image display unit 161 (STEP 5), and the recording operation is finished.

Note that the micro SD card 21 may have a configuration in which the set information, the panel size information and the CRC code constitute one group, and a plurality of groups can be recorded.

[Reading Operation]

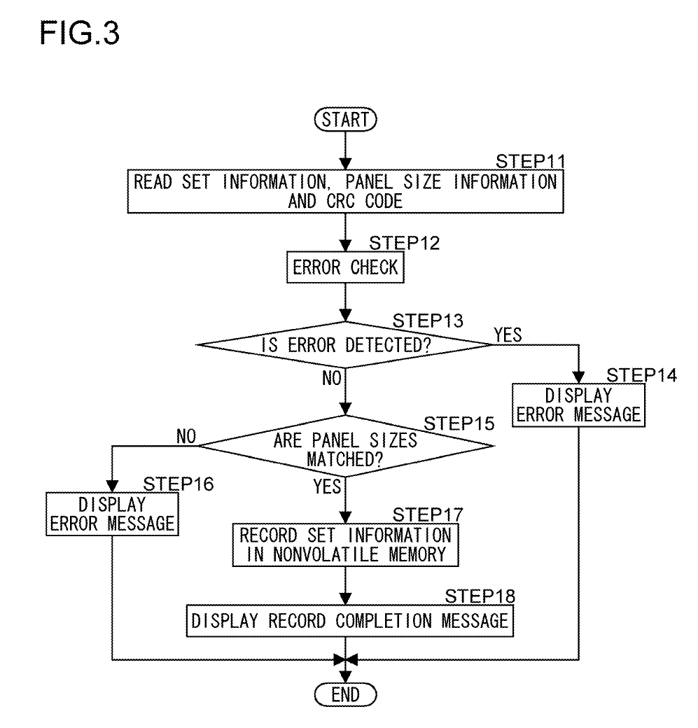

Next, the reading operation of Example 1 of the set information recording system 1 will be described with reference to FIG. 3. FIG. 3 is a flowchart illustrating the reading operation of Example 1 of the set information recording system according to an embodiment of the present invention.

When the set information is read from the set information recording device 20, the set information recording device 20 is connected to the B-CAS slot 11 of the reception/reproduction apparatus 10. Then, for example, the user instructs the micro controller 19 via the user input unit 18 to perform the reading operation. Then, the reception/reproduction apparatus 10 switches to a state where the set information and the additional information (the panel size information and the CRC code in this example) is read out from the set information recording device 20. In this case, the switch process unit 192 performs switching of the circuit connection or the like appropriately so that the set information, the panel size information and the CRC code are read out from the set information recording device 20 via the B-CAS slot 11.

When the set information recording system 1 becomes the above-mentioned state so that the reading operation is started, the set information, the panel size information and the CRC code recorded in the micro SD card 21 of the set information recording device 20 is first read out by the set information control unit 191 of the micro controller 19 via the external memory tool 22 and the B-CAS slot 11 (STEP 11).

The set information control unit 191 newly generates the CRC code on the basis of the set information and the panel size information read in STEP 11. Then, the newly generated CRC code is compared with the CRC code read in STEP 11, so that error check of the set information and the panel size information read out from the set information recording device 20 is performed (STEP 12). Presence or absence of error can be decided on the basis of whether or not the both CRC codes are the same as each other.

If the CRC codes are not the same, namely if an error is detected from the read set information and panel size information (YES in STEP 13), the set information control unit 191 instructs the reproduction process circuit 14 to display an error message without recording the set information read from the set information recording device 20 in the nonvolatile memory 17. Then, the reproduction process circuit 14 generates the image signal in accordance with the instruction, and the image signal is supplied to the image display unit 161 of the reproduction unit 16. Thus, the error message is displayed on the image display unit 161 (STEP 14), and the reading operation is finished.

On the contrary, if the CRC codes are the same, namely if no error is detected from the set information and the panel size information read from the set information recording device 20 (NO in STEP 13), the set information control unit 191 checks whether or not the panel size information recorded in the nonvolatile memory 17 is the same as the panel size information read out in STEP 11 (STEP 15).

Between the reception/reproduction apparatuses 10 having the same panel size information as the equipment information, the set information can be used in both of them with high probability. Therefore, if the panel size information recorded in the nonvolatile memory 17 is the same as the panel size information read out from the set information recording device 20, it can be decided that the set information read out from the set information recording device 20 is appropriate.

If the one panel size information is not the same as the other one, namely if the read set information is not appropriate for the reception/reproduction apparatus 10 (NO in STEP 15), the set information control unit 191 instructs the reproduction process circuit 14 to display an error message without recording the set information read out from the set information recording device 20 in the nonvolatile memory 17. Then, similarly to STEP 14, the error message is displayed on the image display unit 161 (STEP 16), and the reading operation is finished.

On the contrary, if the panel sizes are the same, namely if the read set information is appropriate for the reception/reproduction apparatus 10 (YES in STEP 15), the set information control unit 191 records the read set information in the nonvolatile memory 17 (STEP 17). Then, the set information control unit 191 confirms that the set information is recorded in the nonvolatile memory 17 and instructs the reproduction process circuit 14 to display a message indicating that the recording has finished. Then, the reproduction process circuit 14 generates the image signal in accordance with the instruction, so that the image signal is supplied to the image display unit 161 of the reproduction unit 16. Thus, the message indicating that the recording has finished is displayed on the image display unit 161 (STEP 18), and the reading operation is finished.

With the configuration described above, not only the set information but also the equipment information indicating equipment characteristic of the reception/reproduction apparatus 10 (panel size information in the example described above) is also recorded in the set information recording device 20. Therefore, the reception/reproduction apparatus 10 can decide easily and automatically whether or not the set information that is read out from the set information recording device 20 and is recorded in the reception/reproduction apparatus 10 is appropriate, on the basis of the equipment information. Therefore, even if the set information recording device 20 (or the micro SD card 21 as a part thereof) is mistaken, the mistake is promptly detected so that it is possible to prevent the inappropriate set information from being recorded in the nonvolatile memory 17. In addition, it is possible to record appropriate set information in the nonvolatile memory 17.

In addition, by using the panel size information as the equipment information, it is possible to utilize information that is used in the conventional reception/reproduction apparatus. In other words, the configuration does not require adding new information for identifying the reception/reproduction apparatus 10 to the process of the reception/reproduction apparatus 10. Therefore, it is possible to suppress design change, complication of configuration and cost increase of the reception/reproduction apparatus 10.

Further, the panel size information is useful particularly as information expressing characteristic of the entire reception/reproduction apparatus 10. If the panel size is the same between the reception/reproduction apparatuses 10, not only characteristic of the image display unit 161 (for example, the number of resolution steps or the number of display pixels) but also characteristic of the sound reproduction unit 162 (for example, a size of the speaker and a distance between the speakers, and output characteristic thereof) as well as a grade of the reception/reproduction apparatus 10 (for example, the number of input and output terminals for the image and sound signals and types thereof) is substantially the same so that the reproduction process circuit 14 performs the same process in many cases. Therefore, as described above, between the reception/reproduction apparatuses 10 having the same panel size, the same set information can be used with high probability. Therefore, by performing the decision based on the panel size information, it is possible to decide effectively whether or not the set information is appropriate.

Note that the order of STEP 1 and STEP 2 in FIG. 2 may be changed. In addition, it is desirable to decide in STEP 15 that the panel sizes are the same when the panel size information pieces are completely identical.

In addition, it is possible to adopt a configuration in which the user's operations illustrated in FIGS. 2 and 3 are performed on a menu for general users or on a menu for an administrator or a manufacturer, or are performed by input of a special key code.

### Example 2

In Example 1 described above, it is decided whether or not the set information is appropriate on the basis of equipment characteristic of the reception/reproduction apparatus 10 (equipment information). However, only by the decision method of Example 1, in the case where the set information read out by a reception/reproduction apparatus 10 is the same as that recorded by the reception/reproduction apparatus 10 of the same (or the same model), the set information is always decided to be appropriate regardless of contents thereof. In other words, a difference of contents of the set information (for example, a new one or old one of the set information recorded by the same reception/reproduction apparatus 10) cannot be decided. Therefore, in Example 2, a configuration capable of deciding a difference of contents of the set information will be described. Note that the description in Example 1 can also be applied to this example as long as no contradiction arises, or unless otherwise noted.

[Recording Operation]

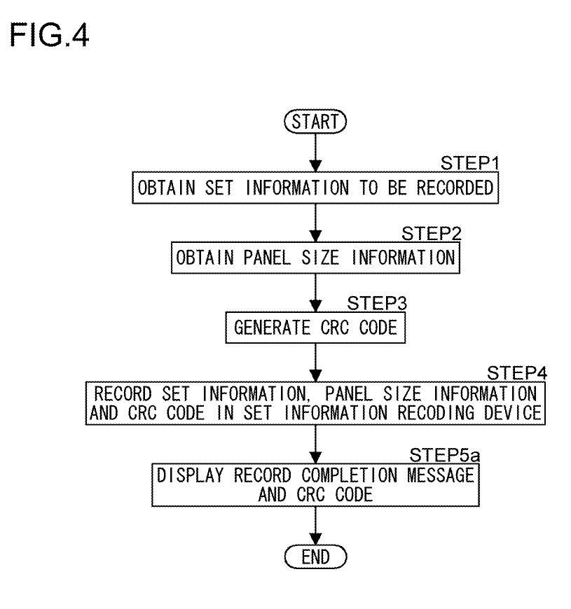

The recording operation of Example 2 of the set information recording system 1 will be described with reference to FIG. 4. FIG. 4 is a flowchart illustrating the recording operation of Example 2 of the set information recording system 1 according to an embodiment of the present invention, and corresponds to FIG. 2 of Example 1. Further, in FIG. 4, a part having the same operation as that in FIG. 2 is denoted by the same step number, and detail description thereof will be omitted.

Similarly to Example 1, in this example too, the set information and the panel size information is obtained, and the CRC code is generated on the basis of them (STEPS 1 to 3). Then, in addition to the set information, the panel size information and the CRC code are recorded in the set information recording device 20 (STEP 4).

However, in this example, when the set information control unit 191 confirms that the set information, the panel size information and the CRC code are recorded in the micro SD card 21, it instructs the reproduction process circuit 14 to display not only the message indicating that the recording is completed but also the CRC code. Then, the reproduction process circuit 14 generates the image signal in accordance with the instruction, and the image signal is supplied to the image display unit 161 of the reproduction unit 16. Thus, the message indicating that the recording is completed and the CRC code are displayed on the image display unit 161 (STEP 5a), and the recording operation is finished.

[Reading Operation]

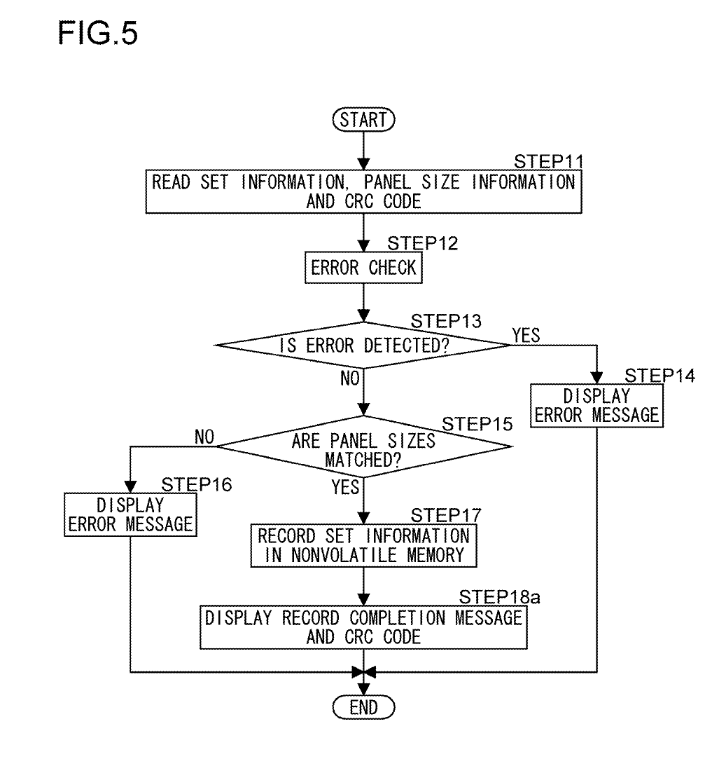

Next, the reading operation of Example 2 of the set information recording system 1 will be described with reference to FIG. 5. FIG. 5 is a flowchart illustrating the reading operation of Example 2 of the set information recording system according to an embodiment of the present invention, and corresponds to FIG. 3 of Example 1. Further, in FIG. 5, a part having the same operation as that in FIG. 3 is denoted by the same step number, and detail description thereof will be omitted.

Similarly to Example 1, in this example too, the set information, the panel size information and the CRC code are read out from the set information recording device 20 (STEP 11), the error check is performed (STEPS 12 and 13), and it is checked whether or not the panel size information is the same (STEP 15). Then, if an error is detected from the read set information and panel size information (YES in STEP 13), or if the set information is decided to be inappropriate (NO in STEP 15), the error message is displayed on the image display unit 161 (STEP 14 or 16), and the reading operation is finished.

On the other hand, if no error is detected from the set information and panel size information (NO in STEP 13) and if it is decided that the set information is appropriate (YES in STEP 15), the read set information is recorded in the nonvolatile memory 17 (STEP 17). Further, in this example, when the set information control unit 191 confirms that the set information is recorded in the nonvolatile memory 17, it instructs the reproduction process circuit 14 to display not only the message indicating that the recording is completed but also the CRC code. Then, the reproduction process circuit 14 generates the image signal in accordance with the instruction, and the image signal is supplied to the image display unit 161 of the reproduction unit 16. Thus, the message indicating that the recording is completed and the CRC code are displayed on the image display unit 161 (STEP 18a), and the reading operation is finished.

With the configuration described above, when the set information recording device 20 record the set information, the equipment information and the generated information supplied from the reception/reproduction apparatus 10, and when the reception/reproduction apparatus 10 reads the set information, the equipment information and the generated information recorded in the set information recording device 20 so as to record the set information, the generated information is displayed on the image display unit 161. The generated information to be displayed is generated on the basis of the set information and the equipment information unlike the equipment information, so it is information different for each set information and equipment information. Therefore, the user can recognize the identity of the set information to be display on the basis of the generated information (in particular, the above-mentioned difference of contents can also recognized). However, it is preferred that the user administrates the generated information by, for example, making a memo of the generated information to be display when the set information, the equipment information and the generated information are recorded in the set information recording device 20 by the reception/reproduction apparatus 10.

Further, when it is decided whether or not the set information is appropriate, on the basis of the generated information as described above, even if the set information recording device 20 (or the micro SD card 21 as a part thereof) is mistaken, the user can promptly recognize the situation so as to rerecord appropriate set information in the nonvolatile memory 17 afterward.

Further, before performing STEP 17, it is possible to perform “display of the CRC code” in STEP 18a, so that the user selects whether or not to record the set information read from the set information recording device 20 in the nonvolatile memory 17 between the “display of the CRC code” and the STEP 17. In this case, if the user selects to record the set information in the nonvolatile memory 17, the process goes to STEP 17. On the contrary, if the user selects not to record, a message indicating the user's selection is displayed, for example, and the reading operation is finished.

With this configuration, even if the set information recording device 20 or the micro SD card 21 is mistaken, it is possible to prevent inappropriate set information from being recorded in the nonvolatile memory 17 in advance.

Further, instead of (or in addition to) the above-mentioned configuration in which the generated information is displayed on the image display unit 161 so as to notify the user, it is possible to notify by reproducing the generated information with the sound reproduction unit 162. However, the configuration of displaying the generated information on the image display unit 161 is preferred because the user can be notified clearly.

In addition, the information other than the CRC code (for example, parity or check sum) may be used as the generated information. However, as described above, the CRC code has higher ability of detecting error than the parity or the check sum that is generated by simple operation. In other words, there is a low possibility that codes generated from different set information are the same by coincidence, so that discriminating ability is high. Therefore, it is preferred to use the CRC code as the generated information, so that it is possible to decide effectively whether or not the set information read from the set information recording device 20 is appropriate.

### Example 3

Next, the recording operation and the reading operation of Example 3 of the set information recording system 1 will be described with reference to the drawings. Note that detailed description of the same operation as that in Example 1 will be omitted.

[Recording Operation]

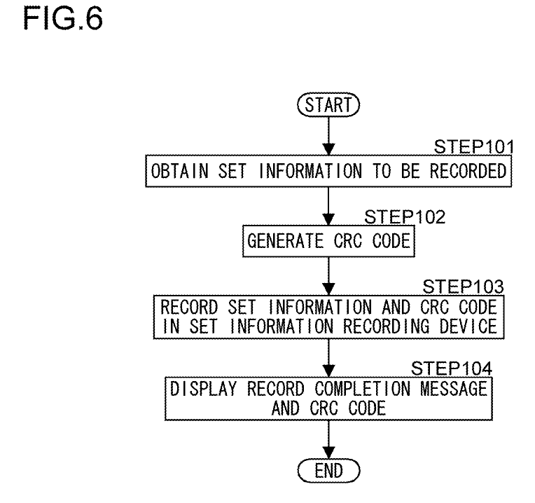

First, the recording operation of Example 3 of the set information recording system 1 will be described with reference to FIG. 6. FIG. 6 is a flowchart illustrating the recording operation of Example 3 of the set information recording system according to an embodiment of the present invention. Note that the recording operation of this example is also an operation of recording the set information and the additional information supplied from the reception/reproduction apparatus 10 by the set information recording device 20.

Similarly to Example 1, the set information recording system 1 becomes a state of performing the recording operation, and the recording operation is started. Then, the set information control unit 191 first reads out and obtains the set information to be recorded from the nonvolatile memory 17 (STEP 101). In addition, the set information control unit 191 generates the additional information on the basis of the obtained set information (STEP 102). Note that a case where the CRC code is generated for example as the additional information is exemplified for specific description.

In this example, the CRC code is generated as the remainder obtained by dividing the bit string (set information) to be operated by a predetermined generating polynomial as described above. The set information control unit 191 records the set information and the CRC code in the micro SD card 21 via the B-CAS slot 11 and the external memory tool 22 (STEP 103).

When it is confirmed that the set information and the CRC code are recorded in the micro SD card 21, the set information control unit 191 instructs the reproduction process circuit 14 to display the message indicating that the recording is completed and the CRC code. Then, the reproduction process circuit 14 generates the image signal in accordance with the instruction so that the image signal is supplied to the image display unit 161 of the reproduction unit 16. Thus, the message indicating that the recording of the set information is completed and the CRC code are displayed on the image display unit 161 (STEP 104), and the recording operation is finished.

Note that the micro SD card 21 may have a configuration in which the set information and the CRC code constitute one group, and a plurality of groups can be recorded.

[Reading Operation]

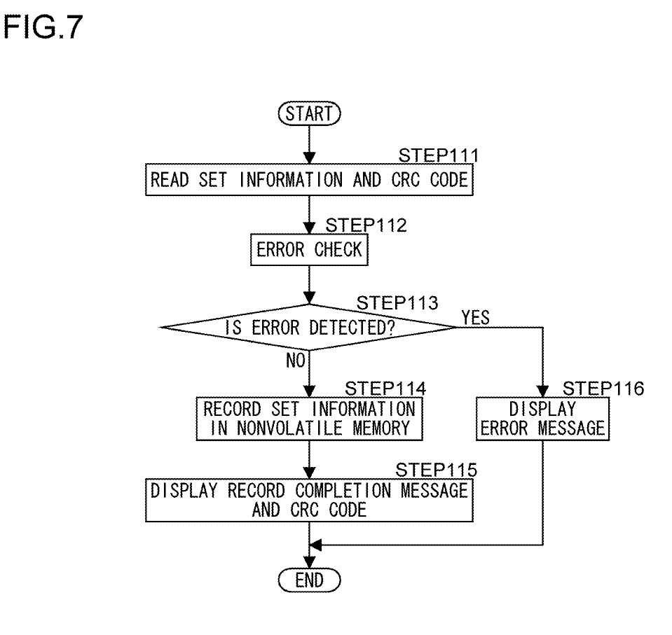

Next, the reading operation of the set information recording system 1 will be described with reference to FIG. 7. FIG. 7 is a flowchart illustrating the reading operation of Example 3 of the set information recording system according to an embodiment of the present invention. Note that the reading operation of this example is also an operation of reading out the set information and the additional information (CRC code in this example) recorded in the set information recording device 20, by the reception/reproduction apparatus 10.

Similarly to Example 1, the set information recording system 1 becomes a state of performing the reading operation, and the reading operation is started. Then, the set information and the CRC code record in the micro SD card 21 of the set information recording device 20 are first read out by the set information control unit 191 of the micro controller 19 via the external memory tool 22 and the B-CAS slot 11 (STEP 111).

The set information control unit 191 newly generates the CRC code on the basis of the set information read out in STEP 111. Then, the newly generated CRC code is compared with the CRC code read out in STEP 111, so as to perform the error check of the set information read out from the set information recording device 20 (STEP 112). Presence or absence of an error can be decided on the basis of whether or not the CRC codes of them are the same.

If the CRC codes are the same, namely if no error is detected from the set information read out from the set information recording device 20 (NO in STEP 113), the set information control unit 191 records the read set information in the nonvolatile memory 17 (STEP 114). Then, the set information control unit 191 confirms that the set information is recorded in the nonvolatile memory 17, and instructs the reproduction process circuit 14 to display the message indicating that the recording is completed and the CRC code. Then, the reproduction process circuit 14 generates the image signal in accordance with the instruction so that the image signal is supplied to the image display unit 161 of the reproduction unit 16. Thus, the message indicating that the recording is completed and the CRC code are displayed on the image display unit 161 (STEP 115), and the reading operation is finished.

On the other hand, if the CRC codes are not the same, namely if an error is detected from the read set information (YES in STEP 113), the set information control unit 191 instructs the reproduction process circuit 14 to display the error message without recording the set information read out from the set information recording device 20 in the nonvolatile memory 17. Then, the reproduction process circuit 14 generates the image signal in accordance with the instruction, so that the image signal is supplied to the image display unit 161 of the reproduction unit 16. Thus, the error message is displayed on the image display unit 161 (STEP 116), and the reading operation is finished.

With the configuration described above, only the set information but also the additional information generated from the set information (the CRC code in the above-mentioned example) is recorded in the set information recording device 20. Therefore, the user can easily decide whether or not the set information that is read out from the set information recording device 20 and is recorded in the reception/reproduction apparatus 10 is appropriate, on the basis of the additional information. Therefore, even if the set information recording device 20 (or the micro SD card 21 as a part thereof) is mistaken, the user can promptly recognize the situation so as to rerecord appropriate set information in the nonvolatile memory 17 afterward.

Specifically, the additional information is displayed on the image display unit 161 when the set information recording device 20 records the set information and the additional information supplied from the reception/reproduction apparatus 10, and when the reception/reproduction apparatus 10 reads out the set information and the additional information recorded in the set information recording device 20 so as to record the set information. Therefore, the user can recognize the identity of the set information (for example, about when the set information is recorded in the set information recording device 20, or from which reception/reproduction apparatus 10 the set information is obtained), on the basis of the displayed additional information. However, it is preferred that the user administrates the additional information by, for example, making a memo of the additional information to be displayed when the set information and the additional information are supplied from the reception/reproduction apparatus 10 to the information recording device 20 to be recorded.

Further, before performing STEP 114, it is possible to perform “display of the CRC code” in STEP 115, so that the user selects whether or not to record the set information read from the set information recording device 20 in the nonvolatile memory 17 between the “display of the CRC code” and the STEP 17. In this case, if the user selects to record the set information in the nonvolatile memory 17, the process goes to STEP 114. On the contrary, if the user selects not to record, a message indicating the user's selection is displayed, for example, and the reading operation is finished.

With this configuration, even if the set information recording device 20 or the micro SD card 21 is mistaken, it is possible to prevent inappropriate set information from being recorded in the nonvolatile memory 17 in advance.

In addition, it is possible to adopt a configuration in which the additional information is generated on the basis of an identification number of the reception/reproduction apparatus 10 or equipment characteristic. However, with this configuration, it may be difficult to distinguish set information obtained from the same or the same type of reception/reproduction apparatuses 10 (namely, decide whether or not it is appropriate) on the basis of the additional information. Therefore, it is more preferred to adopt the configuration in which the additional information generated on the basis of the set information is used as described above, so that the set information can be distinguished effectively.

Further, instead of (or in addition to) the above-mentioned configuration in which the additional information is displayed on the image display unit 161 so as to notify the user, it is possible to notify by reproducing the additional information with the sound reproduction unit 162. However, the configuration of displaying the additional information on the image display unit 161 is preferred because the user can be notified clearly.

In addition, it is possible to adopt a configuration in which the user's operations illustrated in FIGS. 6 and 7 are performed on a menu for general users or on a menu for an administrator or a manufacturer, or are performed by input of a special key code.

In addition, this example exemplifies the case where the additional information is the CRC code, but it may be another type information as long as it is generated on the basis of the set information. However, it is preferred to use information such as the CRC code that is used for existing error check or the like, so that the existing configuration or method can be utilized. In addition, the CRC code has higher ability of detecting error than the parity or the check sum that is generated by simple operation and is similarly used for error check. In other words, there is a low possibility that codes generated from different set information are the same by coincidence, so that discriminating ability is high. Therefore, it is preferred to use the CRC code as the additional information, so that it is possible to decide effectively whether or not the set information read from the set information recording device 20 is appropriate.

<Variations>

In the embodiment described above, the set information recording system 1 including the reception/reproduction apparatus 10 which receives and reproduced broadcasting signals is described, but the present invention may be applied to other electronic equipment than the reception/reproduction apparatus 10.

In addition, the set information recording system 1 illustrated in FIG. 1 can be realized by hardware or by a combination of hardware and software. In addition, when software is used for constituting a part of the set information recording system 1, a portion realized by software corresponds to a functional block of the portion.

Although the embodiments of the present invention are described above, the scope of the present invention is not limited to these embodiments, which can be modified variously in the scope of the present invention without deviating from the spirit thereof.

The present invention can be utilized as a set information recording device for recording the set information of the electronic equipment such as a reception/reproduction apparatus which receives and reproduces television broadcasting, or a set information recording system including the set information recording device.

What is claimed is:

1. A set information recording system comprising:
at least one electronic equipment; and
at least one set information recording device which records set information of the electronic equipment, wherein
the electronic equipment includes a connection unit which communicates with the set information recording device, a recording unit which records set information and equipment information indicating its characteristic, and a deciding unit which decides whether or not the set information input to the electronic equipment is correct,
the set information recording device records the equipment information together with the set information which are input together via the connection unit, and
when the set information and the equipment information are input from the set information recording device to the electronic equipment, the deciding unit decides whether or not the set information input to the electronic equipment is appropriate by comparing the input equipment information with the stored equipment information in the recording unit.

2. A set information recording system according to claim 1, further comprising an image display unit which display an image signal obtained when a reception/reproduction apparatus as the electronic equipment receives and reproduces broadcasting signals, wherein the equipment information is information indicating a size of a display screen of the image display unit.

3. A set information recording system according to claim 1, wherein
the electronic equipment further includes a generated information generating unit which generates generated information on the basis of set information and equipment information input to the set information recording device, and a notifying unit which notifies the generated information,
the set information recording device records the generated information together with the set information and the equipment information which are input together via the connection unit, and
the notifying unit notifies the generated information when the set information, the equipment information and the generated information are input from the electronic equipment to the set information recording device, and when the set information, the equipment information and the generated information are input from the set information recording device to the electronic equipment.

4. A set information recording system according to claim 3, wherein
the electronic equipment is a reception/reproduction apparatus which receives and reproduces broadcasting signals, and
the notifying unit is an image display unit which is capable of displaying an image signal obtained by receiving a broadcasting signal and displays the generated information as an image.

5. A set information recording system according to claim 3, wherein the generated information is a CRC code generated by performing a predetermined operation on the set information and the equipment information.

6. A set information recording device which records set information of electronic equipment and equipment information indicating characteristic of the electronic equipment, and supplies the record set information and equipment information to the electronic equipment or other electronic equipment.

7. An electronic equipment comprising:
a connection unit which communicates with outside;
a recording unit which records set information of the electronic equipment and equipment information indicating characteristic of the electronic equipment; and
a deciding unit which decides whether or not the set information input to the electronic equipment is appropriate, wherein
when the set information and the equipment information are input from outside via the connection unit, the deciding unit decides whether or not the set information input to the electronic equipment is appropriate by comparing the input equipment information with the recorded equipment information in the recording unit.

8. A set information recording system comprising:
at least one electronic equipment; and
at least one set information recording device which record set information of the electronic equipment, wherein
the electronic equipment includes a connection unit which communicates with the set information recording device, a recording unit which records the set information, an additional information generating unit which generates additional information on the basis of the set information input to the set information recording device, and a notifying unit which notifies the additional information,
the set information recording device records the additional information together with the set information which are input together via the connection unit, and
the notifying unit notifies the additional information when the set information and the additional information are input from the electronic equipment to the set information recording device, and when the set information and the additional information are input from the set information recording device to the electronic equipment.

9. A set information recording system according to claim 8, wherein
the electronic equipment is a reception/reproduction apparatus which receives and reproduces broadcasting signals, and
the notifying unit is an image display unit that is capable of displaying an image signal obtained by receiving a broadcasting signal, and displays the additional information as an image.

10. A set information recording system according to claim 8, wherein the additional information is a CRC code that is generated by performing a predetermined operation on the set information.

11. A set information recording device which records set information of electronic equipment and additional information generated on the basis of the set information together, and supplies the record set information and additional information to the electronic equipment or other electronic equipment.

12. Electronic equipment comprising:
a connection unit which communicates with outside;
a recording unit which records set information of the electronic equipment;
an additional information generating unit which generates additional information on the basis of the set information output to outside; and
a notifying unit which notifies the additional information, wherein
the notifying unit notifies the additional information when the set information and the additional information are output via the connection unit, and when the set information and the additional information are input via the connection unit.
